(19) United States
(12) Patent Application Publication
(10) Pub. No.: US 2008/0084135 A1
(43) Pub. Date: Apr. 10, 2008

(54) Universal platform for surface acoustic wave (SAW) based sensors

(75) Inventors: Anil Kumar Ramsesh, Bangalore (IN); Boby Joseph, Bangalore (IN)

Correspondence Address: Bryan Anderson;Honeywell International Inc., 101 Columbia Rd., P.O. Box 2245, Morristown, NJ, 07962, US

(73) Assignee: Honeywell International Inc.

(21) Appl. No.: 11/545,331

(22) Filed: Oct. 10, 2006

(51) Int. Cl. H03H 9/25

(52) U.S. Cl. 310/313 R; 310/315

(57) ABSTRACT

A universal platform for surface acoustic wave (SAW) based sensors uses a selective sensing film coating on a piezoelectric substrate depending upon the application and the measurand to be measured. A SAW substrate with one or more IDTs and associated microcontroller-based electronics with a power supply can be implemented in the context of a common sensor platform. The platform can be mass produced and a selective coating utilized. The selective coatings can be adapted for use in a sensor involving, for example, gas sensing humidity (metal oxide semiconductors, Polymers, Zeolites), pressure, temperature (metal oxides whose conductivity vary with temperature), force, torque, strain, stress and applications associated with a variety of physical parameters.

### TECHNICAL FIELD

Embodiments are generally related to surface acoustic wave (SAW) based sensors. Embodiments are also related to the field of SAW-based sensors for measuring gas concentration, humidity, strain, pressure, temperature, torque, stress, force, and most of the physical parameters. Embodiments are additionally related to universal platform for surface acoustic wave (SAW) based sensors.

### BACKGROUND OF THE INVENTION

Acoustic wave devices have been in commercial use for more than 60 years. The telecommunications industry is the largest consumer, accounting for the use of approximately three billion acoustic wave filters annually, primarily in mobile cell phones and base stations. These components are often provided as surface acoustic wave (SAW) devices, and can act as band pass filters in both the radio frequency and intermediate frequency sections of the transceiver electronics.

Several of the emerging applications for acoustic wave devices as sensors may eventually equal the demand of the telecommunications market. These include automotive applications (e.g., torque, gas concentration and tire pressure sensors), medical applications (e.g., chemical sensors), and industrial and commercial applications (e.g., vapor, humidity, temperature, flow and mass sensors). Acoustic wave sensors are competitively priced, inherently rugged, very sensitive, and intrinsically reliable. Some acoustic wave devices are also capable of being passively and wirelessly interrogated (i.e., no sensor power source required).

Acoustic wave sensors are so named because their detection mechanism constitutes a mechanical or acoustic wave. As the acoustic wave propagates through or on the surface of the material, any changes to the characteristics of the propagation path affect the velocity and/or amplitude of the wave. Changes in velocity can be monitored by measuring the frequency or phase characteristics of the sensor and can then be correlated to the corresponding physical quantity being measured.

An important application of surface acoustic wave (SAW) devices is in the field of physical, chemical and biochemical sensing. Surface acoustic waves are very sensitive to changes in physical properties along the propagation of surface acoustic wave path, which modulates wave parameters such as, for example, propagation time, acoustic impedance, frequency, wave length, etc, including mass loading, conductivity, stress, or the viscosity of liquid. Acoustic wave chemical and biochemical sensors have been popular and successfully used in military and commercial applications. For chemical/biochemical sensing applications, the surface of the delay path (i.e., the piezoelectric member) is generally coated with a chemically selective coating which bonds with the target chemical. This delay line is used in the feedback path of an oscillator circuit.

In one prior art configuration, a sensor chip is provided, upon which at least two surface acoustic wave (SAW) sensing elements are centrally located on a first side (e.g., front side) of the sensor chip. The SAW sensing elements occupy a common area on the first side of the sensor chip. An etched diaphragm is located centrally on the second side (i.e., back side) of the sensor chip opposite to the first side in association with the two SAW sensing elements. Such a configuration thus concentrates the mechanical strain of the sensor system or sensor device in the etched diaphragm, thereby providing high strength, high sensitivity and ease of manufacturing thereof.

In another prior art arrangement, an apparatus can be configured to sense the presence of gases, vapors and liquids using acoustic waves. The apparatus comprises a first part that is configured to generate acoustic waves. The apparatus further comprises a second part having a sensing and acoustic wave guiding device, which is generally configured to sense the presence of such substances and propagate acoustic waves. The first part can be removably fixable to the second part of the apparatus. When the first part is fixed to the second part, the acoustic waves propagate in the second part.

FIG. 1 illustrates a schematic diagram of a SAW-based voltage sensor 100. When a monopolar voltage V₁ is applied at an electrode 110, the biasing voltage is generally equivalent to the voltage V₁. When bipolar voltages, such as V₁ and V₂, are applied across the electrodes 110 and 115 respectively, the biasing voltage is equal to the difference in voltages V₁ and V₂. The voltage applied to the electrodes 110 and 115 varies the electrical field and in turn respectively varies the SAW frequencies F₁ and F₂. A frequency amplifier 120 amplifies the SAW frequencies F₁ and F₂ and a mixer 130 to produce a frequency F, which is the difference between F₁ and F₂.

FIG. 2 illustrates a schematic diagram of a SAW oscillator of flow sensor device 200. The use of a surface-acoustic-wave (SAW) device to measure the rate of gas flow involves the use of a SAW heated using a heater 210 to a suitable temperature above ambient is placed in the path of a flowing gas. A 73-MHz oscillator 240 fabricated on a 128 deg rotated Y-cut lithium niobate substrate and heated to 55° C. above ambient indicates a frequency variation greater than 142 kHz for flow-rate variation from 0 to 1000 cu cm/min. The output of the sensor 200 is generally amplified using an amplifier 220 and a frequency counter 230 that counts the frequency of amplifier output. The frequency count can be used to provide a measurement of volume flow rate, pressure differential across channel ports, or mass flow rate. High sensitivity, wide dynamic range, and direct digital output are among the attractive features of the sensor 200 depicted in FIG. 2.

A sensor platform having the capability of multiple measurand operations does not exist. Such a platform, if implemented, could assist in the mass production of the sensors, which reduces the design cycle time and development cost and can be used for multiple measurand. The technical challenge involves implementing a common sensing concept/technique, electronics (i.e., programmable) and a power supply.

The SAW substrate with IDT and associated microcontroller-based electronics with a power supply is a common platform. The selective coating depends on the capability of the measurand to measure. The platform can be mass produced and by experiment for the required measurand and measuring environment, the selective coating is also generally used. The selective coatings are well known for gas sensing humidity (e.g., metal oxide semiconductors, Polymers, Zeolites), pressure, temperature (e.g., metal oxides whose conductivity vary with temperature), force, torque, strain, stress and most of the physical parameters.

### BRIEF SUMMARY

The following summary is provided to facilitate an understanding of some of the innovative features unique to the embodiments disclosed and is not intended to be a full description. A full appreciation of the various aspects of the embodiments can be gained by taking the entire specification, claims, drawings, and abstract as a whole.

It is, therefore, one aspect of the present invention to provide for an improved surface acoustic wave (SAW) based sensors.

It is another aspect of the present invention to provide for SAW-based sensors for measuring gas concentration, humidity, strain, pressure, temperature, torque, stress, force, flow (e.g., a platinum heater in the SAW path) and/or a variety of other physical parameters.

It is a further aspect of the present invention to provide for a universal platform for surface acoustic wave (SAW) based sensors.

The aforementioned aspects and other objectives and advantages can now be achieved as described herein. An universal platform for surface acoustic wave (SAW) based sensors uses a selective sensing film coating on a piezoelectric substrate depending upon the application and measurand to measure. The invention uses a SAW substrate with IDT and associated micro controller or/and Digital signal processor (DSP) or/and intelligent smart electronics with a power supply and necessary protections as a common platform. The platform is mass produced and by experiment for the required measurand and measuring environment, the selective coating is used. The selective coatings can be adapted for use in sensors for sensing, for example, gas sensing humidity (e.g., metal oxide semiconductors, Polymers, Zeolites), pressure, temperature (e.g., metal oxides whose conductivity vary with temperature), force, torque, strain, stress and a variety of other physical parameters.

### BRIEF DESCRIPTION OF THE DRAWINGS

The accompanying figures, in which like reference numerals refer to identical or functionally-similar elements throughout the separate views and which are incorporated in and form a part of the specification, further illustrate the embodiments and, together with the detailed description, serve to explain the embodiments disclosed herein.

FIG. 1 illustrates a schematic diagram of a SAW-based voltage sensor device;

FIG. 2 illustrates a schematic diagram of a SAW oscillator of flow sensor device;

FIG. 3A illustrates a systematic view of a Surface Acoustic Wave (SAW) based sensor system, which can be implemented in accordance with a preferred embodiment;

FIG. 3B illustrates a systematic view of a heater 350 of Surface Acoustic Wave (SAW) based sensor system, which can be implemented in accordance with a preferred embodiment;

FIG. 4A illustrates a perspective view of a Radio Frequency (RF) wireless Surface Acoustic Wave (SAW) apparatus, which can be implemented in accordance with a preferred embodiment;

FIG. 4B illustrates a perspective view of a wired Surface Acoustic Wave (SAW) apparatus, which can be implemented in accordance with a preferred embodiment;

FIG. 5 illustrates a graph depicting a time domain response to a transmitted signal, in accordance with a preferred embodiment; and

FIG. 6 illustrates a high level flow chart of operations depicting logical operational steps for SAW-based sensors, in accordance with a preferred embodiment.

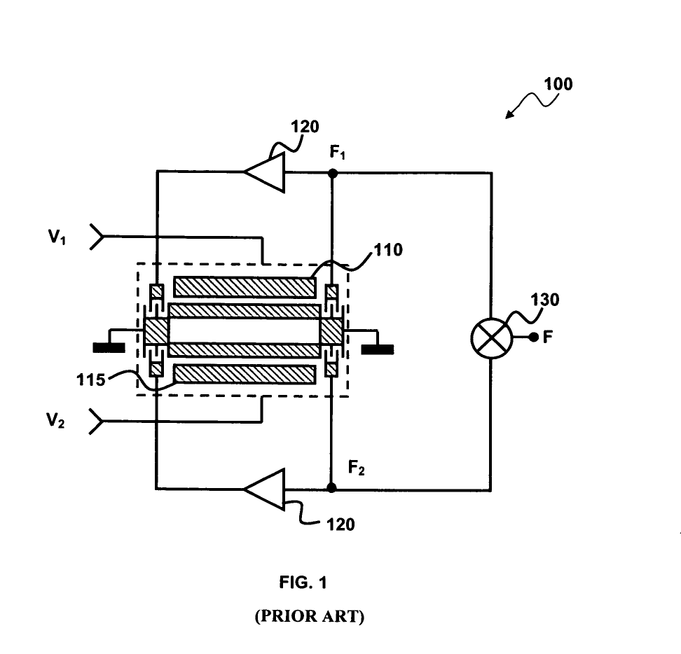

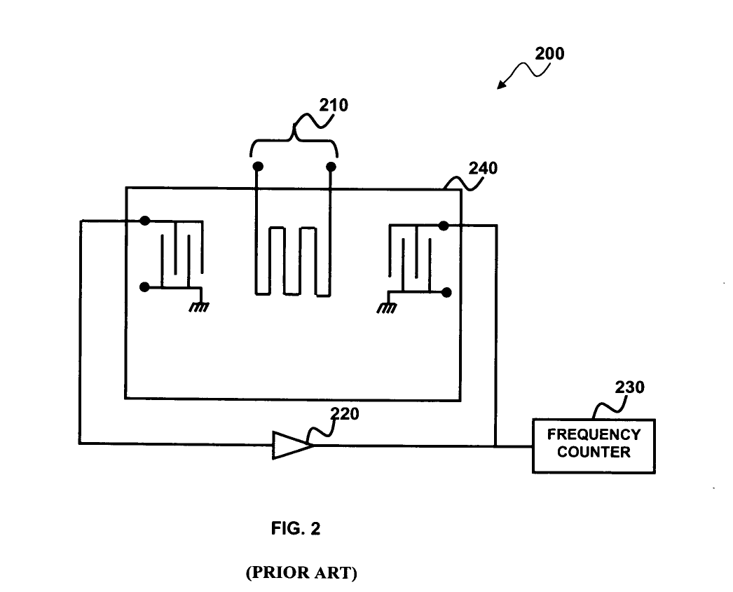

### DETAILED DESCRIPTION

The particular values and configurations discussed in these non-limiting examples can be varied and are cited merely to illustrate at least one embodiment and are not intended to limit the scope thereof.

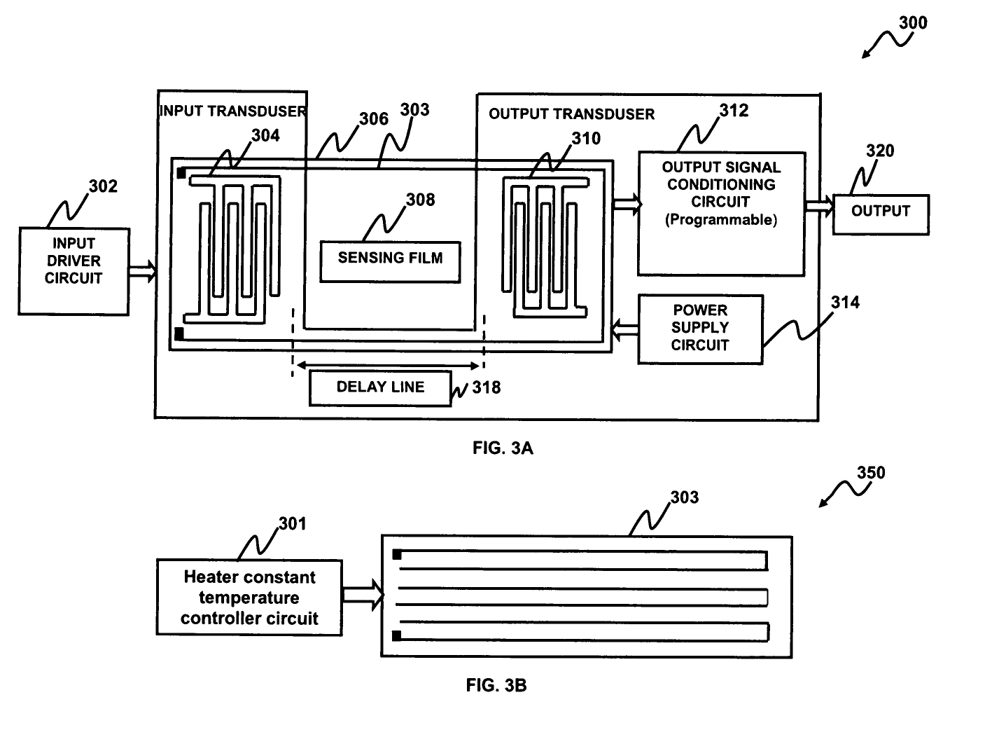

FIG. 3A illustrates a systematic view of a Surface Acoustic Wave (SAW) based sensor system 300, which can be implemented in accordance with a preferred embodiment. System 300 is generally composed of one or more Surface Acoustic Wave (SAW) devices, which constitute specialized micro-acoustic components provided as, for example, a piezoelectric substrate 306 with metallic structures such as input inter-digital transducers (IDTs) 304 and output inter-digital transducers (IDTs) 312 on one side of the substrate. A sensing film 308 is generally deposited on the surface of the piezoelectric substrate 306. The input IDT 304 receives a Radio frequency (RF) request and a transmitted signal (Tₓ signal) from an input driver circuit 302.

On the other side of the substrate 306, a Pt or similar material heater pattern 303 can be provided for heating the sensing element to maintain a constant temperature and reduce the effect of temperature variation on the sensor performance. The heater element can be composed of platinum or a similarly effective material, which possesses a definite positive or negative temperature co-efficient of resistance so that from a measurement of heater resistance, the temperature can be estimated. The heater constant temperature controller circuit can be provided as a part of a microcontroller or DSP or intelligent/smart electronics, with a provision to enable or disable by a firmware for a specific application.

Acoustic wave devices, such as those depicted in FIG. 3A, can be described by the mode of wave propagation through or on a piezoelectric substrate 306. Acoustic waves are generally distinguished from their velocities and displacement directions; many combinations are possible, depending on the material and boundary conditions. The input IDT 304 of each sensor provides the electric field necessary to displace the substrate and thus form an acoustic wave. A delay line 318 causes a time delay in the acoustic wave. The acoustic wave propagates through the substrate 306, where it is converted back to an electric field at the output IDT 310. The output from IDT 310 can then be provided as input signal to a programmable output signal conditioning circuit 312. The measurand is measured based on the conditioned output 320 from the conditioning circuit 312.

The power supply system consisting of suitable protection to reverse polarity, over voltage, short circuit and Electromagnetic compatibility 314 supplies power to the sensor system 300. The SAW substrate with IDTs 304, 310 and associated micro controller and/or DSP and/or smart and/or intelligence based electronics with power supply 314 is a common platform. The selective coating or sensing film 308 depends on the measurand to be measured. The platform or system 300 can be mass produced and/or implemented experimentally for the required measurand and measuring environment. In either case (i.e., mass produced or experimental), the selective coating or sensing film 308 is used. The selective coatings or sensing film 308 are well known for gas sensing humidity, pressure, temperature, force, torque, strain, stress and most other physical parameters.

FIG. 3B illustrates a systematic view of a heater 350 of Surface Acoustic Wave (SAW) based sensor system, which can be implemented in accordance with a preferred embodiment. The heater constant temperature controller circuit 301 is connected to the heater pattern 303 for maintaining constant temperature of sensing element.

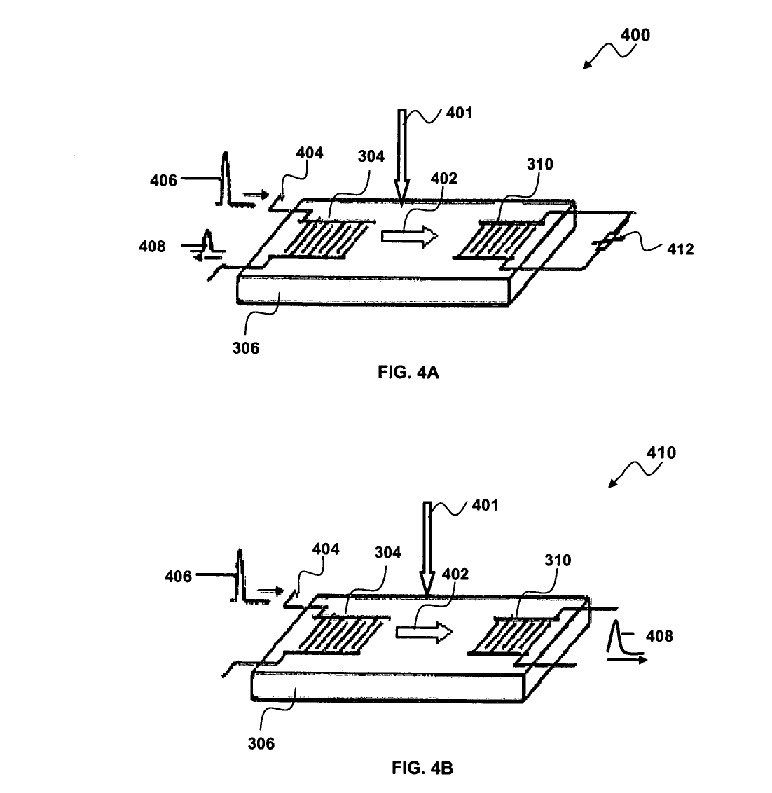

FIG. 4A illustrates a perspective view of a Radio Frequency (RF) wireless Surface Acoustic Wave (SAW) apparatus 400, which can be adapted for use in accordance with a preferred embodiment. Note that in FIG. 3A, identical or similar parts or elements are indicated by identical reference numerals. Thus, the apparatus 300 depicted in FIG. 4A illustration also generally contains the input IDT 304, output IDT 310 and piezoelectric substrate 306, which are described above with respect to FIG. 4A. A physical measurand 401 is applied over the substrate 306. An antenna 404, which communicates with the piezoelectric substrate 406, can receive a radio frequency (RF) request and transmitted signal (Tₓ signal) 406. The apparatus 400 depicted in FIG. 4A can generates a RF response 408 with respect to the RF request and transmitted signal (Tₓ signal) 406. The surface acoustic wave (SAW) 402 propagates from the input IDT 304 to the output IDT 310. The electrical output from output IDT 310 can be obtained across load impedance 412.

FIG. 4B illustrates a perspective view of a wired Surface Acoustic Wave (SAW) apparatus 410, which can be adapted for use in accordance with a preferred embodiment. Note that in FIG. 4A, identical or similar parts or elements are indicated by identical reference numerals. Thus, the depicted in FIG. 4B illustration also generally contains the input IDT 304, output IDT 310, piezoelectric substrate 306, RF request and Tₓ signal 406, physical measurand 401, RF response 408, antenna 404 and SAW 402 which are described above with respect to FIG. 4A.

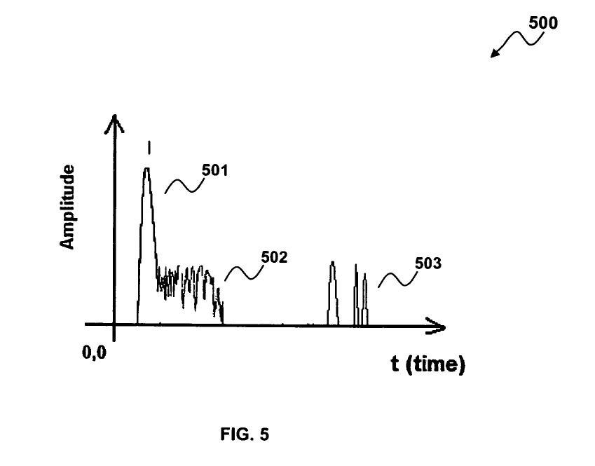

FIG. 5 illustrates a graph 500 depicting a time domain response to a transmitted signal (e.g., Tₓ signal 406), in accordance with a preferred embodiment. The graph 500 generally illustrates the amplitude variation of an input signal 501 and stray reflections 502 with respect to time. The variation of sensor output or reflections 503 with respect to time are also depicted in FIG. 5.

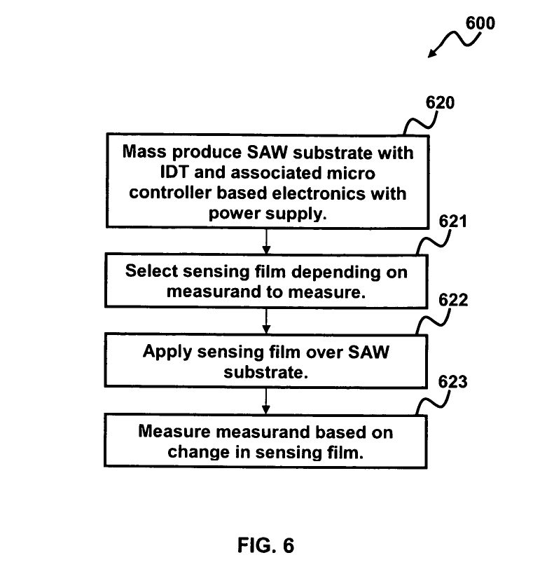

FIG. 6 illustrates a high level flow chart 600 of operations for configuring one or more SAW-based sensors, in accordance with a preferred embodiment. The SAW substrate with IDT and associated microcontroller-based electronics with power supply represents a platform as described earlier. Such a platform can be mass produced as indicated at block 620. A selective coating, depending on the measurand to measure, can be selected as described at block 621. The selective coating is then generally applied over the substrate as depicted at block 622. The selective coatings are well known for gas sensing humidity (metal oxide semiconductors, Polymers, Zeolites), pressure, temperature (metal oxides whose conductivity vary with temperature), force, torque, strain, and stress applications and applications involving a variety of physical parameters. The measurand is measured based on the change in the sensing film as illustrated at block 623.

It will be appreciated that variations of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A universal platform apparatus for a surface acoustic wave (SAW) based sensor, comprising:
an acoustic wave device for generating an acoustic wave, wherein said acoustic wave device comprises a substrate with at least one input inter digital transducer (IDT) configured along at least one side of said substrate in association with at least one heater element and at least one output inter digital transducer (IDT) and at least one sensing film;
an input driver for supplying a radio frequency request and a transmitter signal to said at least one input IDT;
a conditioning circuit for conditioning an output from said at least one output IDT to an output device, thereby providing a universal platform apparatus for SAW-based sensor applications.

2. The apparatus of claim 1 further comprising:
a temperature sensing and constant temperature controller circuit that measures a resistance of said at least one heater element in order to estimate temperature.

3. The apparatus of claim 1 wherein said substrate comprises a piezoelectric material.

4. The apparatus of claim 1 wherein said substrate comprises a metal insulated material.

5. The apparatus of claim 1 wherein said substrate comprises a ceramic material.

6. The apparatus of claim 5 further comprising a thick piezoelectric material configured above said substrate.

7. The apparatus of claim 5 further comprising a thin film piezoelectric coating configuring above said substrate.

8. The apparatus of claim 1 further comprising a power supply for operating said acoustic wave device and said conditioning circuit.

9. The apparatus of claim 3 wherein said sensing film is selectively coated over said substrate.

10. The apparatus of claim 1 wherein a coating of said sensing film is dependent upon at least one measurand to be measured.

11. The apparatus of claim 1 wherein said at least one heater element comprises platinum.

12. A universal platform apparatus for a surface acoustic wave (SAW) based sensor, comprising:
a substrate comprising at least one of the following: a piezoelectric material, a metal insulated material or a ceramic material;
an acoustic wave device for generating an acoustic wave, wherein said acoustic wave device comprises said substrate with at least one input inter digital transducer (IDT) configured along at least one side of said substrate in association with at least one heater element and at least one output inter digital transducer (IDT) and at least one sensing film;
an input driver for supplying a radio frequency request and a transmitter signal to said at least one input IDT;
a conditioning circuit for conditioning an output from said at least one output IDT to an output device, thereby providing a universal platform apparatus for SAW-based sensor applications; and
a temperature sensing and constant temperature controller circuit that measures a resistance of said at least one heater element in order to estimate temperature.

13. The apparatus of claim 12 further comprising a thick piezoelectric material configured above said substrate.

14. The apparatus of claim 12 further comprising a thin film piezoelectric coating configuring above said substrate.

15. The apparatus of claim 12 further comprising a power supply for operating said acoustic wave device and said conditioning circuit.

16. The apparatus of claim 15 wherein said sensing film is selectively coated over said substrate.

17. The apparatus of claim 12 wherein a coating of said sensing film is dependent upon at least one measurand to be measured.

18. The apparatus of claim 12 wherein said at least one heater element comprises platinum.

19. A universal platform apparatus for a surface acoustic wave (SAW) based sensor, comprising:
a substrate comprising at least one of the following: a piezoelectric material, a metal insulated material or a ceramic material;
an acoustic wave device for generating an acoustic wave, wherein said acoustic wave device comprises said substrate with at least one input inter digital transducer (IDT) configured along at least one side of said substrate in association with at least one heater element and at least one output inter digital transducer (IDT) and at least one sensing film, wherein said at least one heater element comprises platinum;
an input driver for supplying a radio frequency request and a transmitter signal to said at least one input IDT;
a conditioning circuit for conditioning an output from said at least one output IDT to an output device, thereby providing a universal platform apparatus for SAW-based sensor applications;
a temperature sensing and constant temperature controller circuit that measures a resistance of said at least one heater element in order to estimate temperature; and
a thin film piezoelectric coating configuring above said substrate.

20. The apparatus of claim 19 further comprising a power supply for operating said acoustic wave device and said conditioning circuit and wherein said sensing film is selectively coated over said substrate.
